(19) United States
(12) Patent Application Publication
(10) Pub. No.: US 2011/0227181 A1
(43) Pub. Date: Sep. 22, 2011

(54) PHOTOELECTRIC CONVERSION FILM-STACKED SOLID-STATE IMAGING DEVICE WITHOUT MICROLENSES, ITS MANUFACTURING METHOD, AND IMAGING APPARATUS

(75) Inventors: Hiroshi INOMATA, Kanagawa (JP); Eiji WATANABE, Miyagi (JP)

(73) Assignee: FUJIFILM CORPORATION, Tokyo (JP)

(21) Appl. No.: 13/049,832

(22) Filed: Mar. 16, 2011

(30) Foreign Application Priority Data
Mar. 17, 2010 (JP) 2010-061620

(51) Int. Cl. H01L 31/0224; H01L 31/18; H01L 31/0232

(52) U.S. Cl. 257/432; 438/65; 257/E31.127; 257/E31.124

(57) ABSTRACT

There are provided a circuit board; a semiconductor substrate bonded to a light-incidence-side surface of the circuit board; a photoelectric conversion film stacked on a layer that is disposed on the light incidence side of the semiconductor substrate; an imaging device chip having signal reading means which is formed in a surface portion of the semiconductor substrate, for reading out, as shot image signals, signals corresponding to signal charge amounts detected by the photoelectric conversion film according to incident light quantities; a transparent substrate bonded to a layer that is disposed on the light incidence side of the photoelectric conversion film with a transparent resin adhesive; and bonding wires which connect connection pads formed on a peripheral portion, not covered with the transparent substrate, of the semiconductor substrate to connection terminals on the circuit board.

The present application claims priority from Japanese Patent Application No. 2010-061620 filed on Mar. 17, 2010, the entire content of which is incorporated herein by reference.

### BACKGROUND OF INVENTION

1. Field of the Invention

The present invention relates to a solid-state imaging device incorporated in an imaging apparatus such as a digital camera. More particularly, the invention relates to a photoelectric conversion film-stacked solid-state imaging device that is configured so as to be suitable for use in an imaging apparatus, as well as its manufacturing method.

2. Description of the Related Art

Solid-state imaging devices have a soft surface because its photodetecting surface is provided with microlenses (top lenses) made of resin or the like and a color filter layer. Therefore, it is necessary to protect the photodetecting surface to prevent formation of scratches and sticking of dust etc. To this end, a transparent substrate such as a glass substrate is bonded to the photodetecting surface with adhesive (refer to JP-A-2003-31782 and JP-A-2008-92417).

However, there are some problems relating to the material of the adhesive. In related solid-state imaging devices such as CCD image sensors and CMOS image sensors, to increase the efficiency of utilization of incident light, microlenses are disposed over respective photodetecting elements. If adhesive having approximately the same refractive index as the microlenses are applied to the surfaces of the microlenses, no light refraction would occur at the surfaces of the microlenses and the function of the microlenses would be impaired, that is, the microlenses could not condense incident light.

For the above reason, the transparent resin as a material of the adhesive should have a smaller refractive index than the microlenses. Furthermore, the reliability of the adhesive is low unless it is made of a material having a small water absorption coefficient. Required to be small in refractive index and water absorption coefficient, the material of the adhesive needs to be selected from only a small number of options, resulting in a problem of cost increase.

JP-A-2004-6834 discloses a technique that the entire surfaces of microlenses are not bonded to a transparent substrate with adhesive; instead, gaps are formed between the microlenses and the transparent substrate and the light condensing efficiency of the microlenses is increased utilizing the refractive index of air. However, a manufacturing step of forming gaps is complex and hence is a factor of manufacturing cost increase. There is another problem that the gaps make it difficult to reduce the thickness of the solid-state imaging device.

### SUMMARY OF INVENTION

An object of the present invention is to provide a compact and thin solid-state imaging device which does not require gaps as mentioned above because it is of a photoelectric conversion film stack type and not be mounted with microlenses and which enables use, as an adhesive material, of a transparent resin whose refractive index is not subjected to any restrictions, as well as a manufacturing method of such a solid-state imaging device and an imaging apparatus incorporating such a solid-state imaging device.

According to an aspect of the invention, a photoelectric conversion film-stacked solid-state imaging device without microlenses, includes: a circuit board; a semiconductor substrate bonded to a light-incidence-side surface of the circuit board; a photoelectric conversion film stacked on a layer that is disposed on the light incidence side of the semiconductor substrate; a signal reading unit formed in a surface portion of the semiconductor substrate, for reading out, as shot image signals, signals corresponding to signal charge amounts detected by the photoelectric conversion film according to incident light quantities; a transparent substrate bonded to a layer that is disposed on the light incidence side of the photoelectric conversion film with a transparent resin adhesive; and a bonding wire which connects connection pads formed on a peripheral portion, not covered with the transparent substrate, of the semiconductor substrate to connection terminal of the circuit board.

According to an aspect of the invention, a manufacturing method of a photoelectric conversion film-stacked solid-state imaging device without microlenses having a semiconductor substrate, a photoelectric conversion film stacked on a layer that is disposed on the light incidence side of the semiconductor substrate, and a signal reading unit formed in a surface portion of the semiconductor substrate, for reading out, as shot image signals, signals corresponding to signal charge amounts detected by the photoelectric conversion film according to incident light quantities, includes the step of: bonding a transparent substrate to a layer that is disposed on the light incidence side of a photoelectric conversion film with a transparent resin adhesive.

According to an aspect of the invention, an imaging apparatus includes a photoelectric conversion film-stacked solid-state imaging device without microlenses according to the above invention.

The invention makes it possible to provide a compact and thin solid-state imaging device in which no gaps need to be formed between a transparent substrate and an imaging device chip because of absence of microlenses, which enables use of a transparent adhesive whose refractive index is not subjected to any restrictions, and which has such a device structure as to be high in mass-productivity and reliability. Furthermore, the invention may miniaturize and increase the reliability of an imaging apparatus incorporating such a solid-state imaging device.

### BRIEF DESCRIPTION OF THE DRAWINGS

FIG. 1 is a functional block diagram of a digital camera according to an embodiment of the present invention;

FIG. 2 is a schematic vertical sectional view of a solid-state imaging device shown in FIG. 1;

FIG. 3 illustrates a manufacturing process of the solid-state imaging device shown in FIG. 2;

FIG. 4 is a schematic sectional view taken along line IV-IV in FIG. 3;

FIG. 5 illustrates a manufacturing step of bonding transparent glass substrates to good imaging device chips, respectively;

FIG. 6 is a schematic sectional view of FIG. 5;

FIG. 7 illustrates a manufacturing step of dicing a semiconductor wafer to which the transparent glass substrates are bonded as shown in FIG. 5;

FIG. 8 is a schematic sectional view of a structure obtained by the dicing of FIG. 7 and including an individual imaging device chip and a transparent glass substrate; and

FIGS. 9A-9C are sectional views illustrating manufacturing steps which are executed after the state of FIG. 8.

### DESCRIPTION OF EXEMPLARY EMBODIMENTS

An embodiment of the present invention will be hereinafter described with reference to the drawings.

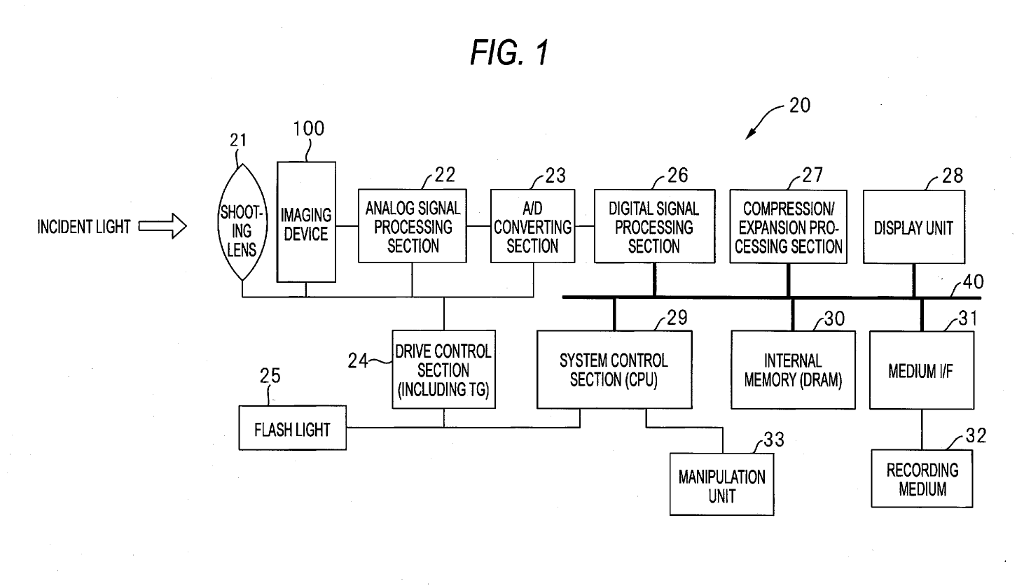

FIG. 1 is a block diagram showing the configuration of a digital camera (imaging apparatus) 20 according to the embodiment of the invention. The digital camera 20 is equipped with a solid-state imaging device 100, a shooting lens 21, an analog signal processing section 22 which performs analog processing such as automatic gain control (AGC) and correlated double sampling on analog image data that is output from the solid-state imaging device 100, an analog-to-digital (A/D) converting section 23 which converts analog image data that is output from the analog signal processing section 22 into digital image data, a drive control section (including a timing generator) 24 which drive-controls the shooting lens 21, the A/D-converting section 23, the analog signal processing section 22, and the solid-state imaging device 100 according to an instruction from a system control section (CPU; described later) 29, and a flash light 25 which emits light according to an instruction from the system control section 29.

The digital camera 20 according to the embodiment is also equipped with a digital signal processing section 26 which captures digital image data that is output from the A/D-converting section 23 and performs interpolation processing, white balance correction, RGB/YC conversion processing, etc. on the digital image data, compression/expansion processing section 27 which compresses image data into JPEG or like image data or expands JPEG or like image data, a display unit 28 which displays a menu and the like and also displays a through-the-lens image or a shot image, the system control section (CPU) 29 which supervises the entire digital camera 20, an internal memory 30 such as a frame memory, a medium interface (I/F) section 31 which performs interfacing with a recording medium 32 for storing JPEG or like image data, and a bus 40 which interconnects the above blocks. A manipulation unit 33 which receives a user instruction is connected to the system control section 29.

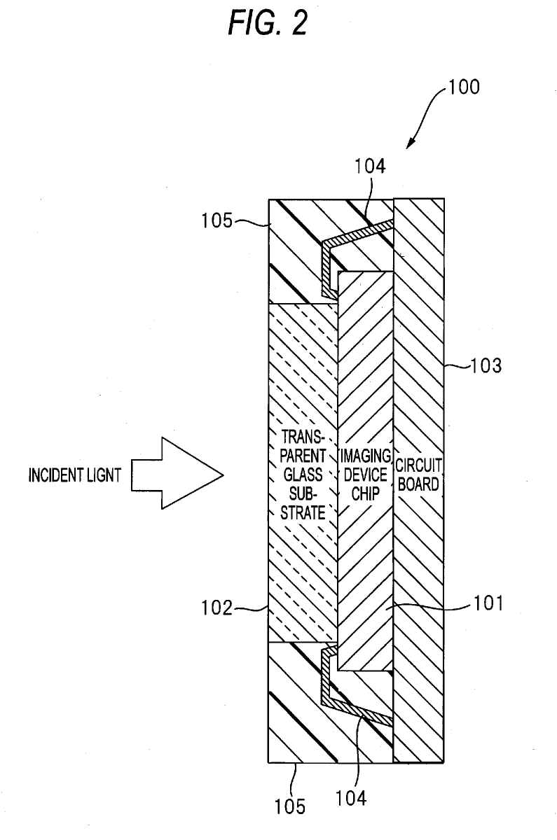

FIG. 2 is a schematic vertical sectional view of the solid-state imaging device 100 shown in FIG. 1. The solid-state imaging device 100 is composed of an imaging device chip 101, a transparent glass substrate 102 which is bonded to an imaging area of the photodetecting surface (front surface) of the imaging device chip 101 with a transparent resin, and a circuit board 103 which is bonded to the back surface of the imaging device chip 101.

The area decreases in order of the circuit board 103, the imaging device chip 101, and the transparent glass substrate 102. The imaging device chip 101 is bonded to a central portion of the circuit board 103, and the transparent glass substrate 102 is bonded to a central portion (imaging area) of the imaging device chip 101. Connection pads are formed in a peripheral portion of the imaging device chip 101, that is, a portion around its imaging area, and the connection pads are connected to the circuit board 103 by wires 104 (wire bonding).

An optically black resin 105 for preventing light reflection is formed in a space that contains the wires 104 and is adjacent to the side surfaces of the imaging device chip 101 and the regions where the connection pads are formed, whereby the wires 104 are protected and stray light is prevented from shining on the imaging device chip 101. The light-incidence-side surface of the black resin 105 is flush with the surface of the transparent glass substrate 102, and the side surfaces of the black resin 105 is flush with the side surfaces of the circuit board 103. As such, the solid-state imaging device 100 has a complete rectangular parallelepiped shape. Therefore, individual products of the solid-state imaging device 100 may be handled easily, and a large number of products of the solid-state imaging device 100 may be stored and transported easily before shipment from a factory.

In attaching the above-configured solid-state imaging device 100 to the remaining part of the digital camera 20 shown in FIG. 1, it is necessary to accurately position the image-forming plane of the shooting lens 21 with respect to the photodetecting surface of the imaging device chip 101. As described later in detail, since the solid-state imaging device 100 according to the embodiment is of a photoelectric conversion film stack type and is not mounted with microlenses, this positioning needs to be performed more accurately than in related CCD image sensors and CMOS image sensors. If the accuracy of the positioning is not sufficiently high, the solid-state imaging device 100 may take only subject images that are poor in resolution.

The above positioning is enabled by attaching the solid-state imaging device 100 to the digital camera 20 in such a manner that the surface of the transparent glass substrate 102 is brought into contact with an assembly reference surface (not shown) of the shooting lens 21 side. However, since the transparent glass substrate 102 used in the embodiment covers only the imaging area of the photodetecting surface of the imaging device chip 101, part of light to shine on the imaging area would be interrupted if assembling work are done using the surface of the transparent glass substrate 102 itself as a reference surface.

However, in the embodiment, since the surface of the black resin 105 which is provided around the transparent glass substrate 102 is flush with the surface of the transparent glass substrate 102, positioning may be performed using the surface of the black resin 105, whereby highly accurate positioning is enabled.

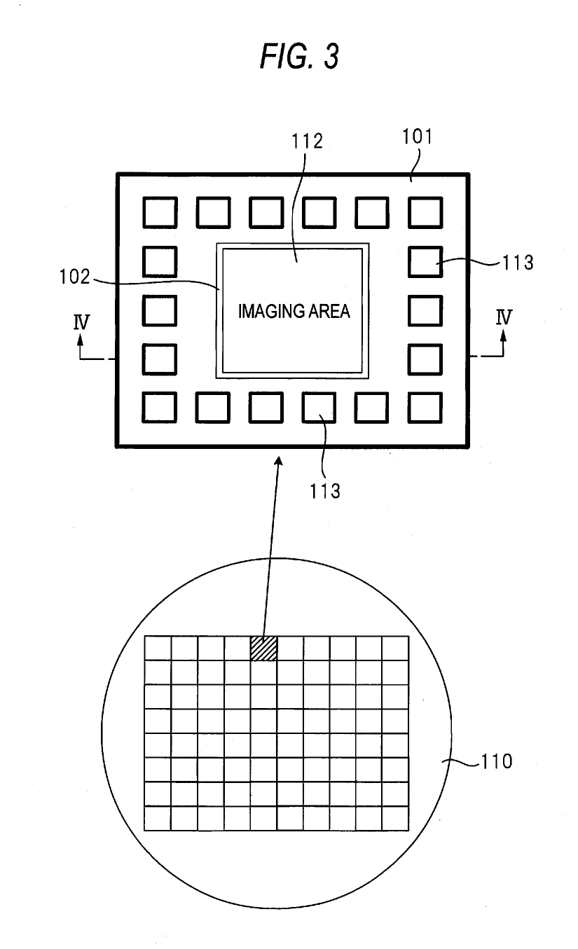

FIG. 3 illustrates a manufacturing process of the imaging device chip 101. A large number of imaging device chips are formed on a semiconductor wafer 110 using semiconductor device manufacturing techniques and film forming techniques and separated into individual imaging device chips 101 by dicing (described later).

In each resulting imaging device chip 101 which is rectangular in a top view, a rectangular imaging area 112 is formed at the center and connection pads 113 are formed around it. A transparent glass substrate 102 is bonded to the imaging area 112 of the photodetecting surface. Wires 104 (see FIG. 2) are bonded to the respective connection pads 113.

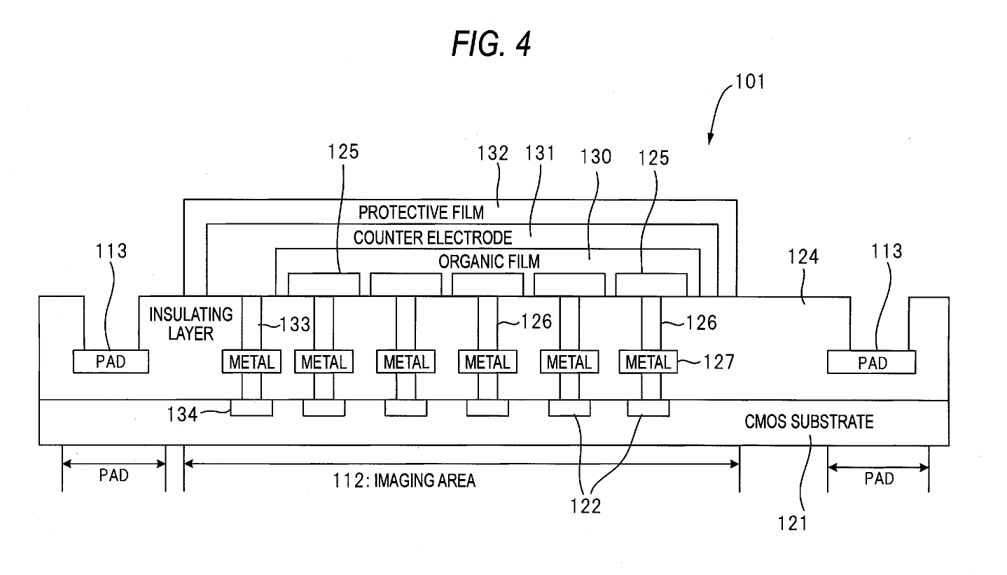

FIG. 4 is a schematic sectional view taken along line IV-IV in FIG. 3. The imaging device chip 101 is formed on a semiconductor substrate 121. Signal charge storage portions 122 corresponding to respective pixels are formed in the semiconductor substrate 121, and signal reading circuits which are MOS transistor circuits (not shown) are formed so as to correspond to the respective pixels as in related CMOS image sensors. Each signal reading circuit reads out, as a shot image signal, via the corresponding connection pad 113, a signal that indicates the amount of charge stored in the corresponding signal charge storage portion 122.

An insulating layer 124 is laid on the top surface of the semiconductor substrate 121, and pixel electrode films 125 are arranged like a two-dimensional array in the imaging area 112 so as to correspond the respective pixels. The pixel electrode films 125 are made of a conductive material such as aluminum or indium tin oxide (ITO).

The pixel electrode films 125 are electrically connected to the respective charge storage portions 122 which correspond to the respective pixels via respective via plugs 126 which are formed vertically in the insulating layer 124. Metal films 127 which are separated from each other are buried in the insulating layer 124 at a halfway position and serve to shield the respective charge storage portions 122 from light.

A single photoelectric conversion film 130 is laid on the pixel electrode films 125 over the entire imaging area. In the embodiment, the photoelectric conversion film 130 is an organic film which generates charge corresponding to the amount of incident light. The organic film 130 is made of metallocyanine, phthalocyanine, or 4H-pyran, for example, and is formed at a thickness of about 1.0 μm.

Therefore, if the positioning is performed in the manner described above with reference to FIG. 2 so that the image-forming plane of the shooting lens 21 (see FIG. 1) is located in the organic film 130 which is about 1.0 μm in thickness, a high-resolution subject image may be taken.

A single transparent counter electrode film made of ITO, for example, is laid on the organic film 130 and is covered with a protective film 132. Where the solid-state imaging device 100 is for taking a color image, a layer of Bayer-arranged color filters of R, G, and B (three primary colors) is laid on the protective film 132 (or a planarization film) and covered with a transparent protective film.

The counter electrode film 131 is connected via a via plug 133 to a high-concentration impurity layer 134 which is formed in the semiconductor substrate 121. A prescribed voltage is applied to the counter electrode film 131 via the high-concentration impurity layer 134, a wiring layer (not shown), and a corresponding connection pad 113.

In the photoelectric conversion film-stacked solid-state imaging device chip 101 having the above configuration, when light shines on the organic film 130 through the protective film 132 and the counter electrode 131, electron-hole pairs are generated in the organic film 130 in a number corresponding to the amount of the incident light. The holes flow to the counter electrode film 131, and the electrons flow to the pixel electrode films 125 and reach the charge storage portions 122, whereby shot image signals corresponding to the amounts of charges stored in the charge storage portions 122 are read out by the signal reading circuits, respectively.

In the photoelectric conversion film-stacked solid-state imaging device chip 101 in which the signal reading circuits are formed in the lower semiconductor substrate 121, incident light may be received by the entire upper photodetecting surface. Unlike in related image sensors, it is not necessary that incident light be condensed by microlenses so as to reach individual photodiodes. Therefore, in selecting a transparent adhesive with which to bond the transparent glass substrate 102 (see FIG. 2) to the protective film 132 (or the protective film formed on the color filter layer), it is not necessary to take into consideration the refractive index of the transparent adhesive. Since a transparent adhesive may be selected with priority given to other factors such as the water absorption coefficient, the reliability of the solid-state imaging device 100 may be increased and a low-cost transparent adhesive may be selected.

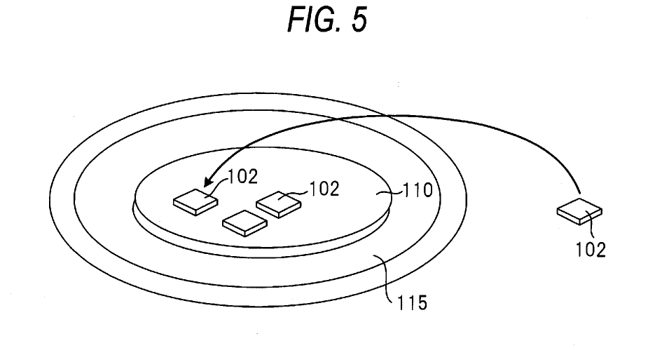

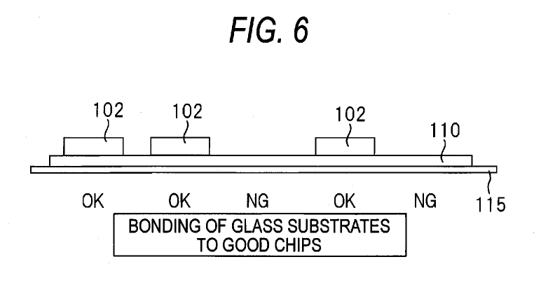

Next, a manufacturing method of the above-described imaging device chip 101 will be described. After a large number of imaging device chips are formed on a semiconductor wafer 110 (see the bottom part of FIG. 3), the semiconductor wafer 110 is placed on a support substrate 115 and individual transparent glass substrates 102 are bonded to the imaging areas of good imaging device chips on the semiconductor wafer 110, respectively, with a transparent resin (see FIG. 5). As shown in FIG. 6, no transparent glass substrates 102 are bonded to defective imaging device chips, the transparent glass substrates 102 serve to mark good ones during manufacture.

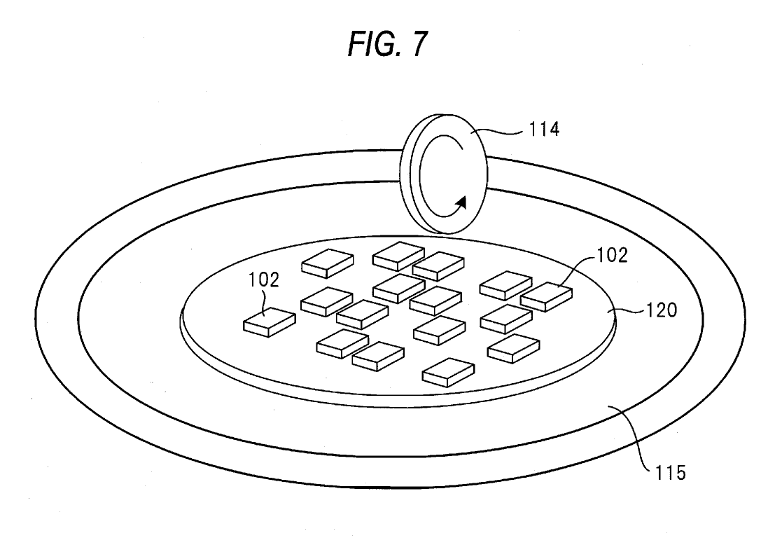

Then, as shown in FIG. 7, dicing is performed using a dicing blade 114 to produce individual imaging device chips 101. The dicing method is not limited to the one using the dicing blade 114, and other methods may be employed such as one using laser light.

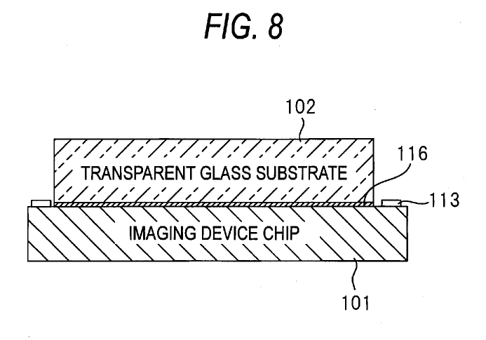

FIG. 8 is a sectional view of a structure including an individual imaging device chip 101 Immediately after the dicing, the transparent glass substrate 102 is merely bonded to the imaging device chip 101 with a transparent resin adhesive 116 and a circuit board 103 shown in FIG. 2 is not attached to the imaging device chip 101. In the state of FIG. 8, each connection pad 113 is a little projected from the surface of the imaging device chip 101 because the recess over each connection pad 113 shown in FIG. 4 is filled with metal.

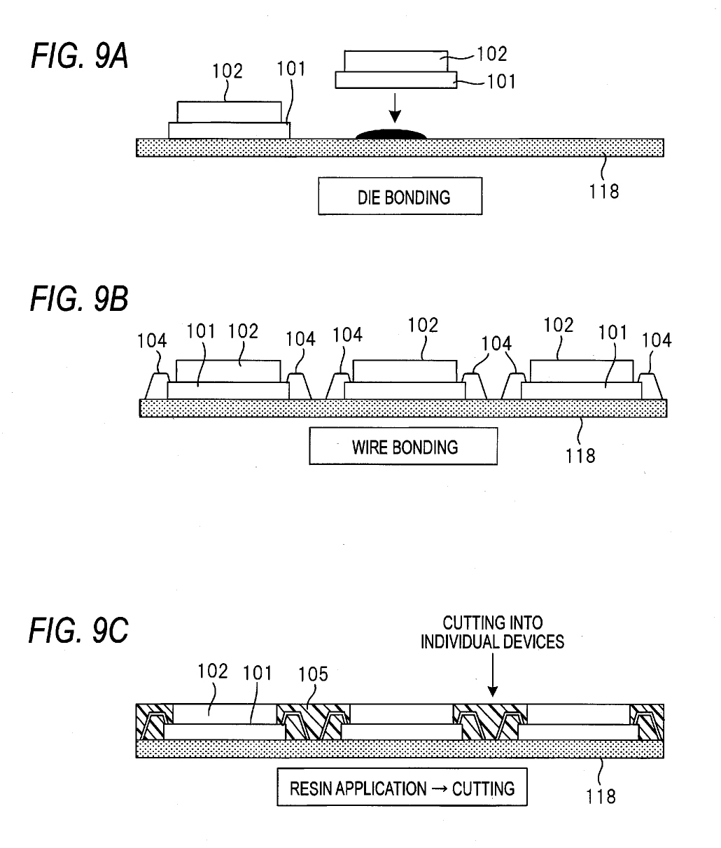

Then, as shown in FIG. 9A, good imaging device chips 101 (i.e., imaging device chips 101 to which transparent glass substrates 102 are bonded) are bonded to a circuit board 118 that has not been divided into individual circuit boards 103 (see FIG. 2). Then, as shown in FIG. 9B, the connection pads 113 of each imaging device chip 101 are connected to respective terminals on the circuit board 118 by wires 104 (wire bonding).

Then, as shown in FIG. 9C, the spaces between the adjoining imaging device chips 101 and the adjoining transparent glass substrates 102 are filled with a black resin 105, whereby the imaging device chips 101 are sealed in. Since the resin 105 contracts thermally, the amount of resin 105 with which to fill the spaces between the adjoining imaging device chips 101 and the adjoining transparent glass substrates 102 is determined taking its volume after the contraction into consideration so that resulting resin members 105 will project a little from the surfaces of the transparent glass substrates 102 after the thermal contraction.

Since the black resin 105 is soft and the transparent glass substrate 102 is made of a hard material, the surface of the black resin 105 may be made flush with the surface of the transparent glass substrate 102 without damaging the surface of the transparent glass substrate 102 by polishing the black resin 105 and the transparent glass substrate 102 using an abrasive that is between them in hardness. Individual solid-state imaging devices 101 as shown in FIG. 2 are obtained by separating the imaging device chips 101 by dicing. Each resulting imaging device chip 101 may be incorporated into a digital camera or the like in COB (chip on board) form, for example.

Since the solid-state imaging device 100 manufactured in the above-described manner is not mounted with microlenses, the material of the adhesive with which to bond the transparent glass substrate 102 to the imaging device chip 101 may be selected from many options and hence may be one that enables reduction in manufacturing cost and increase in reliability. The transparent glass substrate 102 prevents a failure that is caused by a foreign substance stuck to the surface of the imaging device chip 101. Even if a foreign substance is stuck to the surface of the transparent glass substrate 102, it may be wiped away easily.

The solid-state imaging device 100 may be positioned with high accuracy using the surface of the resin 105. Since the resin 105 is an optical black resin, no stray light shines on the imaging device chip 101 and hence images with only little noise may be taken.

Since the resin 105 protects the thin wires 104 physically and prevents contact between adjoining wires 104, the reliability of the solid-state imaging device 100 is increased. Furthermore, since the solid-state imaging device 100 is thinner as a whole than related CCD image sensors, CMOS image sensors, etc., an imaging apparatus may be made more compact and thinner and hence is made suitable for use in small electronic apparatus such as cell phones.

As described above, the manufacturing method according to the embodiment is directed to a photoelectric conversion film-stacked solid-state imaging device without microlenses having a semiconductor substrate, a photoelectric conversion film stacked on a layer that is disposed on the light incidence side of the semiconductor substrate, and signal reading means formed in a surface portion of the semiconductor substrate, for reading out, as shot image signals, signals corresponding to signal charge amounts detected by the photoelectric conversion film according to incident light quantities. The manufacturing method is characterized by comprising the step of bonding a transparent substrate to a layer that is disposed on the light incidence side of a photoelectric conversion film with a transparent resin adhesive.

The manufacturing method according to the embodiment is also characterized by further comprising the steps of forming plural imaging device chips on a semiconductor wafer in which signal reading means are formed, by laying photoelectric conversion films over the semiconductor wafer; and bonding transparent substrates to only good ones of the plural imaging device chips with the transparent resin adhesive.

The manufacturing method according to the embodiment is also characterized by further comprising the steps of separating the plural imaging device chips into individual ones by dicing the semiconductor wafer; die-bonding only the good imaging device chips to a collective circuit board; connecting connection pads formed in a peripheral portion of each of individual semiconductor substrates to connection terminals of the collective circuit board by bonding wires; filling spaces between the good imaging device chips with optically black resin members; and dicing a resulting structure into individual imaging devices having the respective good imaging device chips.

The manufacturing method according to the embodiment is also characterized by further comprising the step, executed before the dicing step, of polishing the optically black resin members and the transparent substrates so that a light-incidence-side surface of each of the optically black resin members becomes flush with a light-incidence-side surface of the corresponding transparent substrate.

Each photoelectric conversion film-stacked solid-state imaging device without microlenses according to the embodiment is characterized by being manufactured by one of the above manufacturing methods.

The photoelectric conversion film-stacked solid-state imaging device without microlenses according to the embodiment is characterized by comprising a circuit board; a semiconductor substrate bonded to a light-incidence-side surface of the circuit board; a photoelectric conversion film stacked on a layer that is disposed on the light incidence side of the semiconductor substrate; signal reading means formed in a surface portion of the semiconductor substrate, for reading out, as shot image signals, signals corresponding to signal charge amounts detected by the photoelectric conversion film according to incident light quantities; a transparent substrate bonded to a layer that is disposed on the light incidence side of the photoelectric conversion film with a transparent resin adhesive; and bonding wires which connect connection pads formed on a peripheral portion, not covered with the transparent substrate, of the semiconductor substrate to connection terminals of the circuit board.

The photoelectric conversion film-stacked solid-state imaging device without microlenses according to the embodiment is also characterized by further comprising an optically black resin member which fills a space that is adjacent to side surfaces of the semiconductor substrate and in which the bonding wires are provided.

The photoelectric conversion film-stacked solid-state imaging device without microlenses according to the embodiment is also characterized in that a light-incidence-side surface of the optically black resin member is flush with a light-incidence-side surface of the transparent substrate.

The photoelectric conversion film-stacked solid-state imaging device without microlenses according to the embodiment is also characterized in being shaped like a rectangular parallelepiped as a result of the space's being filled with the optically black resin member.

Each imaging apparatus according to the embodiment is characterized by comprising one of the above photoelectric conversion film-stacked solid-state imaging device without microlenses.

As such, the embodiment makes it possible to manufacture a compact and thin solid-state imaging device which has such a device structure as to be high in mass-productivity, which is highly reliable because of no hollow spaces, and which is increased in reliability because of the structure that prevents dust etc. the like from entering the solid-state imaging device 100 and reaching the photodetecting surface of the imaging device chip 101.

Being compact and thin and high in mass-productivity and reliability, the photoelectric conversion film-stacked solid-state imaging device without microlenses according to the invention is useful when incorporated in a digital still camera, a digital video camera, a camera-incorporated cell phone, a camera-incorporated electronic apparatus, a monitoring camera, an endoscope, a vehicular camera, etc.

What is claimed is:

1. A photoelectric conversion film-stacked solid-state imaging device without microlenses, comprising:
a circuit board;
a semiconductor substrate bonded to a light-incidence-side surface of the circuit board;
a photoelectric conversion film stacked on a layer that is disposed on the light incidence side of the semiconductor substrate;
a signal reading unit formed in a surface portion of the semiconductor substrate, for reading out, as shot image signals, signals corresponding to signal charge amounts detected by the photoelectric conversion film according to incident light quantities;
a transparent substrate bonded to a layer that is disposed on the light incidence side of the photoelectric conversion film with a transparent resin adhesive; and
a bonding wire which connects connection pads formed on a peripheral portion, not covered with the transparent substrate, of the semiconductor substrate to connection terminal of the circuit board.

2. The photoelectric conversion film-stacked solid-state imaging device without microlenses according to claim 1, further comprising an optically black resin member which fills a space that is adjacent to side surfaces of the semiconductor substrate and in which the bonding wire is provided.

3. The photoelectric conversion film-stacked solid-state imaging device without microlenses according to claim 2, wherein a light-incidence-side surface of the optically black resin member is flush with a light-incidence-side surface of the transparent substrate.

4. The photoelectric conversion film-stacked solid-state imaging device without microlenses according to claim 3, wherein the photoelectric conversion film-stacked solid-state imaging device is shaped like a rectangular parallelepiped as a result of the space's being filled with the optically black resin member.

5. A manufacturing method of a photoelectric conversion film-stacked solid-state imaging device without microlenses having a semiconductor substrate, a photoelectric conversion film stacked on a layer that is disposed on the light incidence side of the semiconductor substrate, and a signal reading unit formed in a surface portion of the semiconductor substrate, for reading out, as shot image signals, signals corresponding to signal charge amounts detected by the photoelectric conversion film according to incident light quantities, comprising the step of:
bonding a transparent substrate to a layer that is disposed on the light incidence side of a photoelectric conversion film with a transparent resin adhesive.

6. The manufacturing method according to claim 5, further comprising:
forming plural imaging device chips on a semiconductor wafer in which a signal reading unit is formed, by laying photoelectric conversion films over the semiconductor wafer; and
bonding transparent substrates to only non-defective ones of the plural imaging device chips with the transparent resin adhesive.

7. The manufacturing method according to claim 5, further comprising:
separating the plural imaging device chips into individual ones by dicing the semiconductor wafer;
die-bonding only the non-defective imaging device chips to a collective circuit board;
connecting connection pads formed in a peripheral portion of each of individual semiconductor substrates to connection terminals of the collective circuit board by bonding wires;
filling spaces between the non-defective imaging device chips with optically black resin members; and
dicing a resulting structure into individual imaging devices having the respective non-defective imaging device chips.

8. The manufacturing method according to claim 7, further comprising the step, executed before the dicing step, of polishing the optically black resin members and the transparent substrates so that a light-incidence-side surface of each of the optically black resin members becomes flush with a light-incidence-side surface of the corresponding transparent substrate.

9. A photoelectric conversion film-stacked solid-state imaging device without microlenses manufactured by a manufacturing method according to claim 5.

10. An imaging apparatus comprising a photoelectric conversion film-stacked solid-state imaging device without microlenses according to claim 1.

11. An imaging apparatus comprising a photoelectric conversion film-stacked solid-state imaging device without microlenses according to claim 9.
